(19) United States
(12) Patent Application Publication
(10) Pub. No.: US 2007/0087121 A1
(43) Pub. Date: Apr. 19, 2007

(54) Apparatus and method for synthesizing chiral carbon nanotubes

(75) Inventors: Ching-Chou Chang, Tu-Cheng (TW); Chi-Chuang Ho, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/450,101

(22) Filed: Jun. 9, 2006

(30) Foreign Application Priority Data
Oct. 11, 2005 (CN) 200510100390.0

(51) Int. Cl. C23C 16/00; B05D 3/10; B29C 71/04

(52) U.S. Cl. 427/249.1; 427/301; 427/532; 118/723 E

(57) ABSTRACT

An exemplary apparatus facilitating the synthesis of chiral carbon nanotubes includes a reaction chamber, and a first electrode and a second electrode disposed in the reaction chamber. The first electrode and the second electrode are spaced apart from each other and define a space therebetween. The space is configured for receiving a catalyst therein. The first electrode is rotatable around an axis to thereby generate an electric field between the first electrode and the second electrode with a periodic variation in direction when a voltage is applied between the first electrode and the second electrode. The axis is substantially perpendicular to a surface of the second electrode facing toward the first electrode. Methods facilitating the synthesis of chiral carbon nanotubes are also provided.

### TECHNICAL FIELD

This invention relates generally to apparatuses and methods for synthesizing carbon nanotubes, and more particularly to an apparatus and method for synthesizing chiral carbon nanotubes.

### BACKGROUND

Carbon nanotubes were first reported in an article by Sumio Iijima entitled “Helical Microtubules of Graphitic Carbon” (Nature, Vol. 354, Nov. 7, 1991, pp. 56-58). Carbon nanotubes have been highlighted as a new functional material expected to have many microscopic and macroscopic applications. Extensive research has been conducted into using carbon nanotubes in various applications, for example in memory devices, gas sensors, microwave shields, electrode pole plates in electrochemical storage units, etc.

Carbon nanotubes are quasi-one-dimensional molecular structures and can be considered as a result of folding graphite (a hexagonal lattice of carbon) layers into cylinders. Carbon nanotubes may be composed of a single shell (single-wall nanotubes) or of several shells (multi-wall nanotubes). The single-wall nanotubes can be thought of as the fundamental cylindrical structure. Currently, the structure of a single-wall carbon nanotube (except for cap region on both ends thereof) is conveniently explained in terms of two vectors Ch and T, where Ch is a chiral vector, representing the circumference of the nanotube, and T is a translational vector, defining the axis direction of the tube. In FIG. 3, the unrolled hexagonal lattice of the nanotube is shown. The equation of the chiral vector Ch is expressed as: Ch=n·a1+m·a2; where n, m are integers (0≦|m|≦n), and a1, a2 are the unit vectors of the hexagonal lattice. Two carbon atoms crystallographically equivalent to each other are placed together according to the equation for Ch. As can be seen in FIG. 3, n and m are equal to 7 and 3 respectively.

The lengths of a1, a2 are both equal to \sqrt{3}a_{cc} , a_{cc} is the bond length of carbon atoms. The length of Ch is equal to a_{cc}·\sqrt{3(n²+nm+m)}. An angle between the vectors Ch and a1 is defined as the chiral angle θ, which denotes the tilt angle of the hexagons with respect to the direction of the tube axis. The chiral angle θ usually is equal to arctan(\sqrt{3}m/(2n+m)). Because of the hexagonal symmetry of the hexagonal lattice, the chiral angle θ usually is ranged from 0 to 30 degrees (i.e., 0°≦|θ|≦30°). Based upon the chiral angle θ, carbon nanotubes can be classified into three types respectively named zigzag, armchair and chiral. As shown in FIG. 3, a zigzag nanotube corresponds to the case of m=0, i.e., θ=0°; an armchair nanotube corresponds to the case of n=m, i.e., θ=30°; and the other cases correspond to chiral nanotubes, i.e., 0<|m|<n and 0°<|θ|<30°.

Carbon nanotubes also exhibit metallic or semiconducting properties depending on their chirality. In particular, the armchair nanotubes always exhibit metallic properties. As for the zigzag and chiral nanotubes, a metallic nanotube meets the condition that (2n+m) is a multiple of 3; for a semiconducting nanotube, (2n+m) is not a multiple of 3. However, Carbon nanotubes produced by a conventional chemical vapor deposition process usually contain a mixture of semiconducting and metallic nanotubes, even when a catalyst (e.g. ball-milled powders of manganese ore) is employed during the process. To realize the practical applications of carbon nanotubes, it is necessary to obtain carbon nanotubes having a specific chirality.

What is needed is to provide an apparatus and method for effectively synthesizing chiral carbon nanotubes having a desired chirality.

### SUMMARY

A preferred embodiment provides an apparatus for synthesizing chiral carbon nanotubes including: a reaction chamber, a first electrode and a second electrode disposed in the reaction chamber. The first electrode and the second electrode are spaced apart from each other and define a space therebetween configured for receiving a catalyst therein. The first electrode is rotatable around an axis to thereby generate an electric field between the first electrode and the second electrode with a periodic variation in direction when a voltage is applied between the first electrode and the second electrode. The axis is substantially perpendicular to a surface of the second electrode facing toward the first electrode.

In another preferred embodiment, a method for synthesizing chiral carbon nanotubes includes the steps of: receiving a catalyst in a space defined between a first electrode and a second electrode, the first electrode and the second electrode being disposed in a reaction chamber and spaced apart from each other; applying a voltage between the first electrode and the second electrode configured for generating an electric field therebetween; rotating the first electrode around an axis configured for inducing the formation of the electric field with a periodic variation in direction, the axis being substantially perpendicular to a surface of the second electrode facing toward the first electrode; introducing a carbon source gas into the reaction chamber; and forming a plurality of chiral carbon nanotubes originating from the catalyst.

Compared with the conventional apparatuses and methods, an apparatus and method in accordance with a preferred embodiment can achieve a plurality of chiral carbon nanotubes having a desired chirality by way of presetting an angular velocity of the rotary motion of the first electrode.

Other advantages and novel features will become more apparent from the following detailed description of embodiments when taken in conjunction with the accompanying drawings.

### BRIEF DESCRIPTION OF THE DRAWINGS

Many aspects of the present apparatus and method for synthesizing chiral carbon nanotubes can be better understood with reference to the following drawings. The components in the drawings are not necessarily to scale, the emphasis instead being placed upon clearly illustrating the principles of the present apparatus and method. Moreover, in the drawings, like reference numerals designate corresponding parts throughout the several views.

FIG. 1 is a schematic, partially cross-sectional view of an apparatus for synthesizing chiral carbon nanotube in accordance with a preferred embodiment;

FIG. 2 is schematic flow chart illustrating a method for synthesizing chiral carbon nanotubes, using the apparatus shown in FIG. 1; and

FIG. 3 shows an unrolled hexagonal lattice of a nanotube with a conventional definition of the chiral vector in the hexagonal lattice.

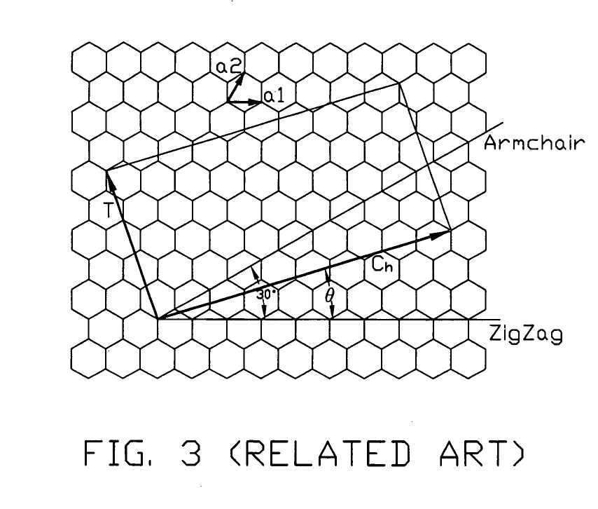

The exemplifications set out herein illustrate at least one preferred embodiment, in one form, and such exemplifications are not to be construed as limiting the scope of the present apparatus and method for synthesizing chiral carbon nanotubes in any manner.

### DETAILED DESCRIPTION OF PREFERRED EMBODIMENTS

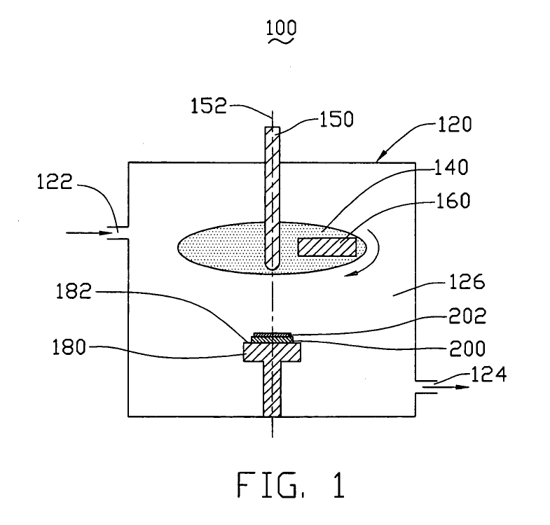

Referring to FIG. 1, a nanotube-growth apparatus 100 for synthesizing chiral carbon nanotubes is shown. The apparatus 100 includes a reactor 120, an electrode 160, and another electrode 180.

The reactor 120 has a reaction chamber 126 configured for receiving a catalyst 202 used for synthesizing chiral carbon nanotubes. The reactor 120 may be a CVD (chemical vapor deposition) reactor with a reaction chamber. The reaction chamber 126 includes a gas inlet 122 and a gas outlet 124 opposite to the gas inlet 122. The gas inlet 122 and the gas outlet 124 usually are located at opposite sidewalls of the reaction chamber 126. Generally, the gas inlet 122 is used for introducing a reactant gas containing carbon source gas (e.g. methane, ethylene, acetylene, etc.) into the reaction chamber 126, and the gas outlet 124 is used for discharging an exhaust gas from the reaction chamber 126.

The electrodes 160 and 180 are disposed in the reaction chamber 126. The electrodes 160 and 180 are spaced apart from each other, and define a space therebetween. The electrode 180 has a surface 182 facing toward the electrode 160. The electrode 160 is rotatable around an axis 152 for generating an electric field between the electrodes 160 and 180 with a periodic variation in direction when a voltage is applied between the electrodes 160 and 180. Preferably, the axis 152 is substantially perpendicular to the surface 182 of the electrode 180.

In the illustrated embodiment, the electrodes 160 and 180 are disposed in an upper part and an opposing lower part of the reaction chamber 126 respectively. The electrodes 160 and 180 usually are in the form of metal plates. The electrode 180 acting as a negative electrode is fixed, while the electrode 160 acting as positive electrode is rotatable about a rotational axle 150. The axis 152 extends through a center of the rotational axle 150. Specifically, the rotational axle 150 is disposed above the electrode 180 and can be actuated to rotate via a motor (not shown). A holder 140 is disposed in the upper part of the reaction chamber 126 and attached to the rotational axle 150. The holder 140 can be a circular plate coaxial with the rotational axle 150. The electrode 160 is attached on the holder 140 and located beside the rotational axle 150. The holder 140 can perform a synchronous rotary motion with the rotational axle 150 to thereby allow the electrode 160 to rotate therewith. It is understood that the electrode 160 may instead be fixed while the electrode 180 is rotatable.

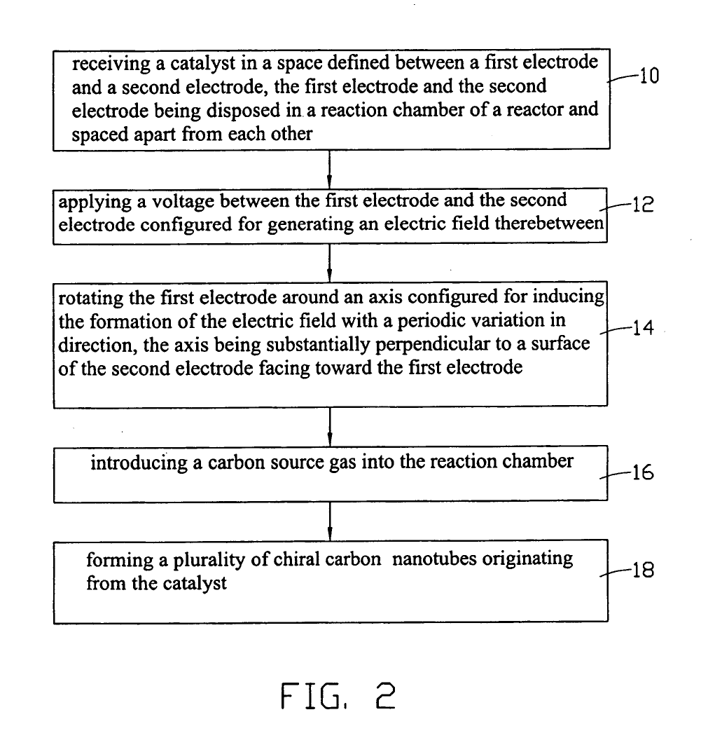

A method for synthesizing chiral carbon nanotubes using such an apparatus 100 will be described in detail with reference to FIGS. 1 and 2. The method includes the following steps:
step 10: receiving a catalyst in a space defined between a first electrode and a second electrode, the first electrode and the second electrode being disposed in a reaction chamber of a reactor and spaced apart from each other;
step 12: applying a voltage between the first electrode and the second electrode configured for generating an electric field therebetween;
step 14: rotating the first electrode around an axis configured for inducing the formation of the electric field with a periodic variation in direction, the axis being substantially perpendicular to a surface of the second electrode facing toward the first electrode;
step 16: introducing a carbon source gas into the reaction chamber; and
step 18: forming a plurality of chiral carbon nanotubes originating from the catalyst.

In step 10, the catalyst 202 is received in a space defined between the electrodes 160 and 180 which are disposed in the reaction chamber 126 of the reactor 120. The catalyst 202 is usually formed by a deposition process, on a surface of a substrate 200. Typically, the substrate 200 is made of a material such as silicon (Si), aluminum oxide (A1₂O₃), glass, etc. The catalyst 202 is in the form of layer and made of a transition metal material such as iron (Fe), cobalt (Co), nickel (Ni), or an alloy thereof.

In step 12, a voltage, for example a direct current voltage, is applied between the electrodes 160 and 180, whereby an electric field is generated between the electrodes 160 and 180. The voltage can be applied by a power supply (not shown) connected with the electrodes 160 and 180 via an external circuit (not shown). Preferably, the electric field strength is usually in the range from 0.5 to 2.0 volts per micron.

In step 14, the rotational axle 150 is rotated by means of a motor (not shown). Accordingly, the holder 140 and the electrode 160 are rotatable about the rotational axle 150 as denoted by an arrow in FIG. 1, while the electrode 180 is fixed. As a result, the electric field generated between the electrodes 160 and 180 has a periodic variation in direction. A chiral angle (hereinafter also denoted by θ) of resultant chiral carbon nanotubes is relevant to the angular velocity (hereinafter also denoted by ω) of the rotary motion of the electrode 160. The larger the angular velocity, the greater the chiral angle of the resultant chiral carbon nanotubes is. Advantageously, the angular velocity of the rotary motion of the electrode 160 is in the range from 0 to 2π/3 radians per second (rad/s), i.e. 0<ω<2π/3 rad/s. Correspondingly, the chiral angle of the resultant chiral carbon nanotubes is in the range from 0° to 30°, i.e. 0°<θ<30°. Additionally, the angular velocity is adjustable and can be preset to give the resulting nanotubes a desired chiral angle.

In step 16, a gaseous raw material, i.e. a carbon source gas, is introduced into the reaction chamber 126 through the gas inlet 122. The carbon source gas can be hydrocarbon gas such as methane, ethylene, acetylene, etc; or a mixture of hydrocarbon gases. Generally, the carbon source gas is introduced into the reaction chamber 126 together with a carrier gas such as an inert gas (e.g. argon) or hydrogen (H₂). Typically, a ratio of the flow rate of the carbon source gas to the carrier gas is in the range from 1:1˜1:10. Thereby, a flow rate of the carbon source gas can be in the range from 20 to 60 sccm (standard cubic centimeter per minute), and a flow rate of the carrier gas can be in the range from 200 to 500 sccm.

In step 18, a plurality of resultant chiral nanotubes extending from the catalyst are formed. The formation of such nanotubes is actually the result of a series of sub-steps. The carbon source gas introduced into the reaction chamber 126 reaches the catalyst 202 which is heated to a predetermined temperature for synthesizing nanotubes. The carbon source gas is at least partially decomposed into carbon atoms and hydrogen gas in a catalytic reaction process with the catalyst 202. The carbon atoms produced by the decomposed carbon source gas will dissolve in the catalyst 202 to grow nanotubes; that is, the carbon source gas is used as source for the carbon in the nanotubes. In addition, due to an effect of the electric field with a periodic variation in direction and an electric field alignment effect originating from the high polarizability of carbon nanotubes, a plurality of chiral carbon nanotubes having a predetermined chiral angle can be obtained. More detailed information on the electric filed alignment effect is taught in an article entitled “Electric-field-directed growth of aligned single-walled carbon nanotubes” (Applied Physics Letters, Nov. 5, 2001, 3155-3157, Vol. 79, No. 19).

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An apparatus for synthesizing chiral carbon nanotubes, comprising:
a reaction chamber; and
a first electrode and a second electrode disposed in the reaction chamber, the first electrode and the second electrode being spaced apart from each other and defining a space therebetween, the space being configured for receiving a catalyst therein, the first electrode being rotatable around an axis to thereby generate an electric field between the first electrode and the second electrode with a periodic variation in direction when a voltage is applied between the first electrode and the second electrode, the axis being substantially perpendicular to a surface of the second electrode facing toward the first electrode.

2. The apparatus of claim 1, wherein the first electrode is rotatable about a rotational axle, the axis extends through a center of the axle.

3. The apparatus of claim 2, further comprising a holder attached to and rotatable with the rotational axle, wherein the first electrode is attached to the holder.

4. The apparatus of claim 3, wherein the holder is a circular plate coaxial with the axis.

5. The apparatus of claim 1, wherein the reaction chamber further comprises a gas inlet and a gas outlet opposite to the gas inlet, the gas inlet and the gas outlet are located at opposite sidewalls of the reaction chamber.

6. The apparatus of claim 1, wherein the first electrode and the second electrode are in the form of metal plates.

7. A method for synthesizing chiral carbon nanotubes, comprising the steps of:
receiving a catalyst in a space defined between a first electrode and a second electrode, the first electrode and the second electrode being disposed in a reaction chamber and spaced apart from each other;
applying a voltage between the first electrode and the second electrode configured for generating an electric field therebetween;
rotating the first electrode around an axis configured for inducing the formation of the electric field with a periodic variation in direction, the axis being substantially perpendicular to a surface of the second electrode facing toward the first electrode;
introducing a carbon source gas into the reaction chamber; and
forming a plurality of chiral nanotubes originating from the catalyst using the carbon source gas as a source for the carbon which forms the nanotubes.

8. The method of claim 7, wherein the electric field is in the range from 0.5 to 2.0 volts per micron.

9. The method of claim 7, wherein the first electrode rotates around the axis with an angular velocity ω in the range of 0<ω<2π/3 radians per second.

10. The method of claim 9, wherein the angular velocity is a constant angular velocity.

11. The method of claim 9, wherein the chiral carbon nanotubes have a chiral angle θ in the range of 0°<θ<30°.

12. The method of claim 7, wherein the carbon source gas is selected from the group consisting of methane, ethylene, acetylene and mixtures thereof.

13. An apparatus for synthesizing chiral nanotubes, comprising:
a reaction chamber including an inlet configured for introducing a gaseous raw material therein; and
a couple of electrodes disposed in the reaction chamber and spaced apart from each other with a space defined therebetween, the space being configured for receiving a catalyst therein, one of the couple of electrodes being rotatable relative to the other one for generating an electric field between the couple of electrodes with a periodic variation in direction when a voltage is applied on the couple of electrodes.

14. The apparatus of claim 13, wherein the one of the couple of electrodes is rotatable about a rotational axle which is substantially perpendicular to a surface of the other one of the couple of electrodes facing toward the one of the couple of electrodes.
